(19) United States
(12) Patent Application Publication
(10) Pub. No.: US 2021/0179891 A1
(43) Pub. Date: Jun. 17, 2021

(54) POLISHING SLURRY COMPOSITION FOR SHALLOW TRENCH ISOLATION PROCESS

(71) Applicant: KCTECH CO., LTD., Gyeonggi-do (KR)

(72) Inventors: Kwang Soo PARK, Gyeonggi-do (KR); Jun Ha HWANG, Gyeonggi-do (KR); Jung Yoon KIM, Gyeonggi-do (KR); Nak Hyun CHOI, Gyeonggi-do (KR)

(73) Assignee: KCTECH CO., LTD., Gyeonggi-do (KR)

(21) Appl. No.: 17/121,770

(22) Filed: Dec. 15, 2020

(30) Foreign Application Priority Data
Dec. 16, 2019 (KR) 10-2019-0167920

(51) Int. Cl. C09G 1/02; C09G 1/16; H01L 21/321

(52) U.S. Cl. CPC C09G 1/02; H01L 21/3212; C09G 1/16

(57) ABSTRACT

A polishing slurry composition for a shallow trench isolation (STI) process is provided. The polishing slurry composition includes abrasive particles, a nonionic polymer, and a polar amino acid.

### CROSS-REFERENCE TO RELATED APPLICATION

This application claims the benefit of Korean Patent Application No. 10-2019-0167920, filed on Dec. 16, 2019, in the Korean Intellectual Property Office, the disclosure of which is incorporated herein by reference.

### BACKGROUND

### 1. Field of the Invention

Example embodiments relate to a polishing slurry composition for a shallow trench isolation (STI) process.

### 2. Description of the Related Art

As semiconductor devices become diverse and highly integrated, finer pattern forming techniques are being used, and the surface structure of the semiconductor devices is becoming more complex and a step difference between surface films is also widening accordingly. As a flattening technique for removing a step difference in a specific film formed on a substrate in the manufacture of semiconductor devices, a chemical mechanical polishing (CMP) process is used. For example, as a process for removing an insulating film formed in an excessive amount for interlayer insulation, a process for flattening the insulating film for shallow trench isolation (STI) performing an insulation function between an interlayer dielectric (ILD) and a chip and a process for forming metal conductive films such as wiring, a contact plug, a via contact, etc. have been widely used.

So-called selective polishing properties of increasing polishing rate of an insulating film layer and decreasing polishing rate of a polysilicon film layer to protect a pattern polysilicon membrane during the STI process are required. Particularly, loss of the polysilicon membrane must be reduced even when proceeding an overpolishing operation on cell type patterns.

On the other hand, when polishing selectivity in the STI process is too high, dishing may occur and degradation of element characteristics may be induced as the insulating film layer buried in the trench is being overpolished. In particular, this dishing problem may have a significant adverse effect on performance and reliability of the element by causing a step difference between an active area and a field area in an element in which the trench is ultra-micronized.

### SUMMARY

The present disclosure is to solve the foregoing problems, and an aspect of the present disclosure is to provide a polishing slurry composition for a shallow trench isolation (STI) process, the polishing slurry composition which removes a residual oxide film, has a function of suppressing surface detects in wafers, and can reduce scratches by having a high polishing rate for a silicon oxide film and a high selectivity for a polysilicon film (stop layer) at the same time, enabling polishing stop and dishing of the polysilicon membrane during overpolishing, and adjusting polishing amount after exposing a polishing stop layer in a pattern wafer.

However, the problems to be solved in the present disclosure are not limited to the foregoing problems, and other problems not mentioned herein would be clearly understood by one of ordinary skill in the art from the following description.

According to an aspect, there is provided a polishing slurry composition for an STI process including abrasive particles, a nonionic polymer, and a polar amino acid.

The abrasive particles may include at least one of a metal oxide, an organic or inorganic matter-coated metal oxide, and the metal oxide in a colloidal state, and the metal oxide may include at least one of ceria, silica, zirconia, alumina, titania, barium titania, germania, mangania, and magnesia.

The abrasive particles may be manufactured by a liquid phase method, and the abrasive particles may be dispersed so that the surface of the abrasive particles may have a positive charge.

The abrasive particles may include primary particles having a particle size of 5 nm to 150 nm and secondary particles having a particle size of 30 nm to 300 nm.

The abrasive particles may be present in an amount of 0.1 wt % to 10 wt % in the polishing slurry composition.

The nonionic polymer may be composed of a polyether skeleton including a hydroxy group.

The nonionic polymer may include at least one of glycerin, diacylglycerine, triacylglycerine, polyglycerine, polyglycerine fatty acid ester, polyoxyalkylene diglyceryl ether, polyoxyalkylene polyglyceryl ether, polyoxyethylene polyglyceryl ether, polyoxypropylene polyglyceryl ether, and glycerin polyglyceryl ether.

The nonionic polymer may have a weight average molecular weight of 300 to 2,000.

The nonionic polymer may be present in an amount of 0.1 wt % to 1.0 wt % in the polishing slurry composition.

The polar amino acid may include an amino acid having an uncharged R group.

The polar amino acid may include at least one of glutamine, threonine, serine, asparagine, cysteine, and tyrosine.

The polar amino acid may be present in an amount of 0.1 wt % to 1.0 wt % in the polishing slurry composition.

The polishing slurry composition may further include at least one dispersion aid among polyethylene glycol, polypropylene glycol, polyvinylpyrrolidone, polyoxyalkylene alkyl ether, polyoxyalkylene alkyl ester, polyoxyethylene methyl ether, polyethylene glycol sulfonic acid, polyvinyl alcohol, polyethylene oxide, polypropylene oxide, polyalkyl oxide, polyoxyethylene oxide, polyethylene oxide-propylene oxide copolymer, cellulose, methyl cellulose, methyl hydroxyethyl cellulose, methyl hydroxypropyl cellulose, hydroxyethyl cellulose, carboxymethyl cellulose, carboxymethyl hydroxyethyl cellulose, sulfoethyl cellulose, and carboxymethyl sulfoethyl cellulose.

The dispersion aid may be present in an amount of 0.001 wt % to 1.0 wt % in the polishing slurry composition.

The polishing slurry composition may have a pH range of 3 to 6.

The polishing slurry composition may have a zeta potential of +5 mV to +70 mV.

The polishing slurry composition may have a polishing selectivity of a silicon oxide film to a polysilicon film of 30:1 to 60:1 in an STI process of a semiconductor device.

A dishing amount in a silicon oxide film region after polishing the polysilicon film may be 300 Å or less.

Additional aspects of examples will be set forth in part in the description which follows and, in part, will be apparent from the description, or may be learned by practice of the disclosure.

According to example embodiments, a polishing slurry composition for an STI process may reduce loss of a polysilicon membrane even when proceeding an overpolishing operation on the cell type patterns as the polishing slurry composition has an excellent polishing stop function for the polysilicon membrane. At the same time, the polishing slurry composition has an excellent effect of preventing dishing of an insulating film, and enables adjusting of an effective dishing level. Further, the polishing slurry composition may maintain a relatively high insulating film-removal rate, may have an excellent flatness improving effect after polishing, may be free from residues after STI polishing of a semiconductor device, may decrease the dishing amount of a silicon oxide film, and may reduce scratches.

### DETAILED DESCRIPTION

Hereinafter, example embodiments will be described in detail with reference to the accompanying specification. When it is determined that a detailed description related to a related known function or configuration may make the purpose of the present disclosure unnecessarily ambiguous in describing the present disclosure, the detailed description will be omitted here. Also, terms used herein are defined to appropriately describe the example embodiments and thus may be changed depending on a user, the intent of an operator, or a custom of a field to which the present disclosure pertains. Accordingly, the terms must be defined based on the following overall description of the present specification.

In the whole present specification, when any member is positioned “on” the other member, this not only includes a case that the any member is brought into contact with the other member, but also includes a case that another member exists between two members.

In the whole present specification, if a prescribed part “includes” a prescribed element, this means that another element can be further included instead of excluding another element.

Hereinafter, a polishing slurry composition for a shallow trench isolation (STI) process according to the present disclosure will be described in detail with reference to example embodiments. However, the present disclosure is not limited to such example embodiments.

A polishing slurry composition for an STI process according to an example embodiment includes abrasive particles, a nonionic polymer, and a polar amino acid.

A polishing slurry composition for an STI process according to an example embodiment may reduce loss of the polysilicon membrane even when proceeding an overpolishing operation on the cell type patterns as the polishing slurry composition has an excellent polishing stop function for the polysilicon membrane. At the same time, the polishing slurry composition has an excellent effect of preventing dishing of an insulating film, and enables adjusting of an effective dishing level. Further, the polishing slurry composition may maintain a relatively high insulating film-removal rate, may have an excellent flatness improving effect after polishing, may be free from residues after STI polishing of a semiconductor device, may decrease the dishing amount of a silicon oxide film, and may reduce scratches.

According to an aspect, the abrasive particles may include at least one of a metal oxide, an organic or inorganic matter-coated metal oxide, and the metal oxide in a colloidal state, and the metal oxide may include at least one of ceria, silica, zirconia, alumina, titania, barium titania, germania, mangania, and magnesia.

According to an aspect, the abrasive particles may be colloidal ceria dispersed as positive charges. The colloidal ceria dispersed as positive charges is mixed with an adding solution activated into a positive charge so that higher step difference-removing performance and automatic polishing stop function may be implemented.

According to an aspect, the abrasive particles may be manufactured by a liquid phase method, and the abrasive particles may be dispersed so that the surface of the abrasive particles has a positive charge. Although the abrasive particles may include abrasive particles manufactured by the liquid phase method, the present disclosure is not limited thereto. The abrasive particles may be manufactured by applying a sol-gel method of generating a chemical reaction of an abrasive particle precursor in an aqueous solution and growing a crystal to obtain fine particles, a coprecipitation method of precipitating abrasive particle ions in the aqueous solution, a hydrothermal synthesis method of forming abrasive particles under high temperatures and high pressures, or the like to the liquid phase method. The abrasive particles manufactured by the liquid phase method are dispersed so that the surface of the abrasive particles may have a positive charge.

According to an aspect, the shape of the abrasive particles may include at least one of a spherical shape, a square shape, an acicular shape, and a plate shape, and the shape of the abrasive particles may desirably be the spherical shape.

According to an aspect, the abrasive particles may be monocrystalline. When monocrystalline abrasive particles are used, the monocrystalline abrasive particles may achieve a scratch reduction effect, may improve dishing, and may improve cleaning ability after polishing compared to polycrystalline abrasive particles.

According to an aspect, the abrasive particles may include primary particles having a particle size of 5 nm to 150 nm and secondary particles having a particle size of 30 nm to 300 nm. An average particle diameter of the abrasive particles is an average particle diameter value of a plurality of particles within a view field range that may be measured by scanning electron microscope analysis or dynamic light scattering. In the particle size of the primary particles, the particle size of the primary particles should be 150 nm or less to secure particle uniformity, and polishing rate may be lowered when the particle size of the primary particles is less than 5 nm. In the particle size of the secondary particles in the polishing slurry composition, cleaning ability is lowered, and defects are excessively generated on a waver surface if small particles are excessively generated due to a milling operation when the particle size of the secondary particles is less than 30 nm. As an overpolishing operation is conducted when the particle size of the secondary particles is more than 300 nm, it becomes difficult to control selectivity, and there is a possibility that dishing, erosion and surface defects are generated. As a slurry composition for an STI process dispersed as a positive charge has an abrasive particle size of 100 nm, it is advantageous in terms of scratch defects.

According to an aspect, the abrasive particles may include mixed particles having a multi-dispersion type particle distribution in addition to single-sized particles. For example, the mixed particles may have a bimodal type particle distribution by mixing two types of abrasive particles having different average particle sizes, a particle size distribution showing three peaks by mixing three types of abrasive particles having different average particle sizes, or a multi-dispersion type particle distribution by mixing four or more types of abrasive particles having different average particle sizes. The mixed particles may expect effects of having more excellent dispersibility and reducing scratches on the wafer surface by mixing relatively large abrasive particles with relatively small abrasive particles.

According to an aspect, the abrasive particles may be present in an amount of 0.1 wt % to 10 wt % in the polishing slurry composition. There is a problem of decreasing the polishing speed when the abrasive particles are present in an amount of less than 0.1 wt % in the polishing slurry composition, and the polishing speed is too high, and surface defects may be generated by adsorbability of the particles remained on the surface due to an increase in the number of abrasive particles when the abrasive particles are present in an amount of more than 10 wt % in the polishing slurry composition.

According to an aspect, the nonionic polymer may be composed of a polyether skeleton including a hydroxy group.

According to an aspect, the nonionic polymer may include at least one of glycerin, diacylglycerine, triacylglycerine, polyglycerine, polyglycerine fatty acid ester, polyoxyalkylene diglyceryl ether, polyoxyalkylene polyglyceryl ether, polyoxyethylene polyglyceryl ether, polyoxypropylene polyglyceryl ether, and glycerin polyglyceryl ether.

According to an aspect, the nonionic polymer may have a weight average molecular weight of 300 to 2,000. Performance of a poly film-protecting film is deteriorated to result in a lower polishing selectivity when the nonionic polymer has a weight average molecular weight of less than 300, and it is apprehended that agglomeration phenomenon will occur, viscosity will increase, and preservation stability of the polishing slurry composition will be reduced when the nonionic polymer has a weight average molecular weight of more than 2,000.

According to an aspect, the nonionic polymer may be present in an amount of 0.1 wt % to 1.0 wt % in the polishing slurry composition. A problem that polishing rate of a polysilicon film is not improved may arise when the nonionic polymer is present in an amount of less than 0.1 wt % in the polishing slurry composition, and a problem that residues are remained may arise as the polishing operation is not sufficiently carried out by a polymer network when the nonionic polymer is present in an amount of more than 1.0 wt % in the polishing slurry composition.

According to an aspect, the polar amino acid may be an amino acid in which a side chain in chemical structure of amino acid has polarity, and may desirably include an amino acid having an uncharged side chain at a neutral pH value.

According to an aspect, the polar amino acid may include at least one of glutamine, threonine, serine, asparagine, cysteine, and tyrosine.

According to an aspect, the polar amino acid may be present in an amount of 0.1 wt % to 1.0 wt % in the polishing slurry composition. A desired polishing selectivity may not be obtained as a silicon oxide film and a polysilicon film do not show selective polishing performance when the polar amino acid is present in an amount of less than 0.1 wt % in the polishing slurry composition, and a problem that the temporal stability of the polishing slurry composition is reduced when the polar amino acid is present in an amount of more than 1.0 wt % may occur.

According to an aspect, the polishing slurry composition may further include at least one dispersion aid among polyethylene glycol, polypropylene glycol, polyvinylpyrrolidone, polyoxyalkylene alkyl ether, polyoxyalkylene alkyl ester, polyoxyethylene methyl ether, polyethylene glycol sulfonic acid, polyvinyl alcohol, polyethylene oxide, polypropylene oxide, polyalkyl oxide, polyoxyethylene oxide, polyethylene oxide-propylene oxide copolymer, cellulose, methyl cellulose, methyl hydroxyethyl cellulose, methyl hydroxypropyl cellulose, hydroxyethyl cellulose, carboxymethyl cellulose, carboxymethyl hydroxyethyl cellulose, sulfoethyl cellulose, and carboxymethyl sulfoethyl cellulose.

According to an aspect, the dispersion aid may be present in an amount of 0.001 wt % to 1.0 wt % in the polishing slurry composition. An automatic polishing stop function for the polysilicon film is deteriorated when the dispersion aid is present in an amount of less than 0.001 wt % in the polishing slurry composition, and there is a problem that the agglomeration phenomenon and scratches occur by reacting the dispersion aid within the polishing slurry composition when the dispersion aid is present in an amount of more than 1.0 wt % in the polishing slurry composition.

According to an aspect, the polishing slurry composition may have a pH range of 3 to 6. There is a problem that agglomeration occurs as dispersion stability is rapidly deteriorated when the polishing slurry composition has a pH value deviated from the pH range.

According to an aspect, the polishing slurry composition may be used by concentrating or diluting the polishing slurry composition in the preparation process.

According to an aspect, the polishing slurry composition may be provided in a two-liquid form in which the mixed solution is used after separately preparing a polishing solution and an adding solution and mixing the polishing solution with the adding solution immediately before polishing to obtain a mixed solution, or in one-liquid form in which the polishing solution is mixed with the adding solution. When the polishing slurry composition is used in the two-liquid form, STI patterns of the polysilicon film are free from residues, dishing preventing performance is improved, and high selectivity may be obtained so that the polishing slurry composition has an excellent ability of removing a step difference of the pattern wafer.

According to an aspect, the polishing slurry composition may be a positive slurry composition showing a positive charge. The polishing slurry composition may have a zeta potential of +5 mV to +70 mV. Due to positively charged abrasive particles, the polishing slurry composition may be a positive slurry composition showing a positive charge, and may reduce the generation of scratches by maintaining high dispersion stability, thereby preventing the abrasive particles from being agglomerated.

According to an aspect, the polishing slurry composition may have a polishing selectivity of a silicon oxide film to a polysilicon film of 30:1 to 60:1 in an STI process of a semiconductor device.

According to an aspect, the polysilicon film may include an undoped polysilicon film, a phosphorous-doped polysilicon film, or both thereof.

According to an aspect, a dishing amount in a silicon oxide film region after polishing the polysilicon film may be 300 Å or less. When the polishing slurry composition shows an excessively high polishing selectivity, although the dishing amount may be increased as the silicon oxide film region is overpolished, the dishing amount is less by including a nonionic polymer composed of a polyether skeleton including a hydroxy group.

A polishing slurry composition for an STI process according to the present disclosure may provide a slurry which has a high polishing rate for the polysilicon membrane, and simultaneously has a high polishing rate for the silicon oxide film and a high polishing rate of the polysilicon membrane by including a nonionic polymer composed of a polyether skeleton including a hydroxy group, and a polar amino acid. Further, a polishing slurry composition for an STI process according to the present disclosure may provide a slurry composition showing a polysilicon-polishing stop function and an excellent dishing level at the same time, and enable dishing to be controlled. Further, a polishing slurry composition for an STI process according to the present disclosure may provide a slurry composition having an excellent scratch reduction effect.

Hereinafter, the present disclosure will be described in detail with reference to an example and a comparative example.

However, the following example and comparative example are illustrative only, and the contents of the present disclosure are not limited thereto.

Polishing Performance of Pattern Wafer

### Example 1

After adding 2.5 wt % of colloidal ceria abrasive particles having a particle size of 60 nm, 0.5 wt % of polyglycerol having a weight average molecular weight of 750 as a nonionic polymer, and 0.25 wt % of L-serine as an abrasive regulator, a polishing slurry composition for an STI process having a pH value of 4.5 was prepared.

### Comparative Example 1

After adding 2.5 wt % of colloidal ceria abrasive particles having a particle size of 60 nm, 0.2 wt % of polyglycerol, 0.1 wt % of picolinic acid, and 0.002 wt % of poly (maleic anhydride) copolymers (PMAC), a polishing slurry composition having a pH value of 3.5 was prepared.

[Polishing Conditions]

1. Polisher: AP-300 (300 mm, CTS Co., Ltd.)

2. Pad: IC 1000 (DOW Corporation)

3. Polishing time: 60 seconds

4. Platen revolutions per minute (RPM): 130 rpm

5. Spindle RPM: 123 rpm

6. Pressure: 4.5 psi

7. Flow rate: 250 ml/min

8. Wafers used: TEOS 2 μm Blanket Wafer, STI Poly Pattern Wafer (Trench 2,000 Å) (Poly 2,000 Å) (TEOS 4,000 Å)

The following Table 1 shows polishing rates per second (ΔOxide) of a silicon oxide film, and polishing amounts (Δpoly) and dishing values of a polysilicon membrane in the pattern wafer when polishing an oxide film blanket wafer and a pattern wafer respectively according to the aforementioned polishing conditions by using the polishing slurry composition of Example 1 and the polishing slurry composition of Comparative Example 1.

TABLE 1

| | | | Comparative | |
|---|---|---|---|---|
| | | | Example 1 | Example 1 |
| pH | | | 3.5 | 4.5 |
| Flow rate (slurry:additive) | | | 250:0 | 250:0 |
| ΔOxide (Å/sec) | | | 101.4 | 103.1 |
| | Pattern/Space | Δpoly | 290 | 28 |
| | 100/100 | Dishing | 1147 | 260 |
| | Pattern/Space | Δpoly | 227 | 19 |
| | 50/50 | Dishing | 1018 | 253 |

Overpolishing: 1,000 Å

Referring to Table 1, it can be confirmed that a high polishing rate of the oxide film is maintained, and a polishing stop function and an excellent dishing level of the polysilicon film are shown at the same time when carrying out a polishing operation using the polishing slurry composition according to Example 1 compared to when carrying out the polishing operation using the polishing slurry composition according to Comparative Example 1.

Scratch Measurement

Defects of substrates polished using polishing slurry compositions for STI processes of Examples 2 to 4 and a polishing slurry composition of Comparative Example 2 were measured.

A substrate cleaning process included performing a cleaning process by using Standard Cleaning-1 (SC-1), i.e., a mixed cleaning solution of ammonia water, hydrogen peroxide and water for 5 seconds and additionally performing a cleaning process by using hydrogen fluoride (HF) for 30 seconds. ATI-XP was used as defect measuring equipment.

The following Table 2 shows polishing rates per second (ΔOxide) of the silicon oxide film, and polishing amounts (Δpoly), dishing values, and scratches of the polysilicon membrane in the pattern wafer when polishing the oxide film blanket wafer and the pattern wafer respectively according to the aforementioned polishing conditions by using a mixed solution obtained by mixing the polishing slurry composition of Example 1, the polishing slurry composition of Comparative Example 1, and an additive composition. The additive composition used in the present Examples includes a nonionic polymer, histidine, and lactic acid.

TABLE 2

| | | Compar- | | | |
|---|---|---|---|---|---|
| | | ative | | | |
| | | Exam- | Exam- | Exam- | Exam- |
| | | ple 2 | ple 2 | ple 3 | ple 4 |
| Flow rate (slurry:additive) | | 175:75 | 175:150 | 175:75 | 175:50 |
| ΔOxide (Å/sec) | | 51.9 | 75.3 | 74.1 | 73.5 |
| Pattern/Space | Δpoly | 3 | 3 | 4 | 4 |
| 100/100 | Dishing | 15 | 245 | 265 | 291 |
| Pattern/Space | Δpoly | 2 | 4 | 6 | 7 |
| 50/50 | Dishing | 11 | 113 | 180 | 208 |

| | | | | |
|---|---|---|---|---|
| Scratches | Δ | ⊚ | ⊚ | ⊚ |

Overpolishing: 1,000 Å

⊚: less than 3 scratches
Δ: less than 10 scratches

Referring to Table 2, it can be seen that a polishing slurry composition for STI process has a high polishing rate for the polysilicon membrane, is free from a silicon oxide film residue, and allows scratches to be reduced by including colloidal ceria abrasive particles, polyglycerine as a nonionic polymer including a hydroxy group, and L-serine that is a polar amino acid.

Although the above-mentioned Examples have been described by limited Examples, those skilled in the art may apply various modifications and alterations from the above-mentioned description. For example, appropriate results can be achieved although described techniques are carried out in a different order from a described method, and/or described elements are combined or mixed in a different form from the described method, or replaced or substituted with other elements or equivalents. Therefore, other embodiments, other Examples, and equivalents to patent claims belong to the scope of the patent claims to be described later.

What is claimed is:

1. A polishing slurry composition for a shallow trench isolation (STI) process, the polishing slurry composition comprising:
abrasive particles;
a nonionic polymer; and
a polar amino acid.

2. The polishing slurry composition of claim 1, wherein
the abrasive particles comprise at least one selected from the group consisting of a metal oxide, an organic or inorganic matter-coated metal oxide, and
the metal oxide in a colloidal state, and the metal oxide comprises at least one selected from the group consisting of ceria, silica, zirconia, alumina, titania, barium titania, germania, mangania, and magnesia.

3. The polishing slurry composition of claim 1, wherein the abrasive particles are manufactured by a liquid phase method, and the abrasive particles are dispersed so that a surface of the abrasive particles has a positive charge.

4. The polishing slurry composition of claim 1, wherein the abrasive particles comprise primary particles having a particle size of 5 nm to 150 nm and secondary particles having a particle size of 30 nm to 300 nm.

5. The polishing slurry composition of claim 1, wherein the abrasive particles are present in an amount of 0.1 wt % to 10 wt % in the polishing slurry composition.

6. The polishing slurry composition of claim 1, wherein the nonionic polymer is composed of a polyether skeleton including a hydroxy group.

7. The polishing slurry composition of claim 1, wherein the nonionic polymer comprises at least one selected from the group consisting of glycerin, diacylglycerine, triacylglycerine, polyglycerine, polyglycerine fatty acid ester, polyoxyalkylene diglyceryl ether, polyoxyalkylene polyglyceryl ether, polyoxyethylene polyglyceryl ether, polyoxypropylene polyglyceryl ether, and glycerin polyglyceryl ether.

8. The polishing slurry composition of claim 1, wherein the nonionic polymer has a weight average molecular weight of 300 to 2,000.

9. The polishing slurry composition of claim 1, wherein the nonionic polymer is present in an amount of 0.1 wt % to 1.0 wt % in the polishing slurry composition.

10. The polishing slurry composition of claim 1, wherein the polar amino acid comprises an amino acid having an uncharged R group.

11. The polishing slurry composition of claim 1, wherein the polar amino acid comprises at least one selected from the group consisting of glutamine, threonine, serine, asparagine, cysteine, and tyrosine.

12. The polishing slurry composition of claim 1, wherein the polar amino acid is present in an amount of 0.1 wt % to 1.0 wt % in the polishing slurry composition.

13. The polishing slurry composition of claim 1, further comprising:
at least one dispersion aid selected from the group consisting of polyethylene glycol, polypropylene glycol, polyvinylpyrrolidone, polyoxyalkylene alkyl ether, polyoxyalkylene alkyl ester, polyoxyethylene methyl ether, polyethylene glycol sulfonic acid, polyvinyl alcohol, polyethylene oxide, polypropylene oxide, polyalkyl oxide, polyoxyethylene oxide, polyethylene oxide-propylene oxide copolymer, cellulose, methyl cellulose, methyl hydroxyethyl cellulose, methyl hydroxypropyl cellulose, hydroxyethyl cellulose, carboxymethyl cellulose, carboxymethyl hydroxyethyl cellulose, sulfoethyl cellulose, and carboxymethyl sulfoethyl cellulose.

14. The polishing slurry composition of claim 13, wherein the dispersion aid is present in an amount of 0.001 wt % to 1.0 wt % in the polishing slurry composition.

15. The polishing slurry composition of claim 1, wherein pH of the polishing slurry composition ranges from 3 to 6.

16. The polishing slurry composition of claim 1, wherein the polishing slurry composition has a zeta potential of +5 mV to +70 mV.

17. The polishing slurry composition of claim 1, wherein the polishing slurry composition has a polishing selectivity of a silicon oxide film to a polysilicon film of 30:1 to 60:1 in an STI process of a semiconductor device.

18. The polishing slurry composition of claim 17, wherein a dishing amount in a silicon oxide film region after polishing the polysilicon film is 300 Å or less.
